(19) United States
(12) Patent Application Publication
(10) Pub. No.: US 2026/0113062 A1
(43) Pub. Date: Apr. 23, 2026

(54) HIGH-FREQUENCY POWER DIVIDING CIRCUIT AND ANTENNA MODULE

(71) Applicant: Murata Manufacturing Co., Ltd., Nagaokakyo-shi (JP)

(72) Inventors: Ryotaro OHASHI, Nagaokakyo-shi (JP); Shinya MIZOGUCHI, Nagaokakyo-shi (JP); Masaya OKAZAKI, Nagaokakyo-shi (JP); Yoshihisa KIMURA, Nagaokakyo-shi (JP); Kengo ONAKA, Nagaokakyo-shi (JP)

(73) Assignee: Murata Manufacturing Co., Ltd., Nagaokakyo-shi (JP)

(21) Appl. No.: 19/357,190

(22) Filed: Oct. 14, 2025

(30) Foreign Application Priority Data
Oct. 17, 2024 (JP) 2024-182065

(51) Int. Cl. H04B 1/00; H03D 7/00

(52) U.S. Cl. CPC H04B 1/0064; H03D 7/00

(57) ABSTRACT

A high-frequency signal is input to a first node. A high-frequency signal is output from each of a plurality of second nodes. A first branch transmission line connects the first node to each of the plurality of second nodes. The first branch transmission line includes a plurality of cascade-connected dividers, each of which has one input node and two output nodes. At least one of the dividers is an unequal divider with a distribution ratio of 2 or less. The first branch transmission line is configured to equally divide a high-frequency power input to the first node to the plurality of second nodes.

### CROSS-REFERENCE TO RELATED APPLICATION

The present application claims priority to Japanese patent application JP 2024-182065, filed Oct. 17, 2024, the entire contents of which being incorporated herein by reference.

### TECHNICAL FIELD

The present disclosure relates to a high-frequency power dividing circuit and an antenna module.

### BACKGROUND ART

An antenna module that uses a power divider to divide a high-frequency signal from a single mixer to multiple high-frequency integrated circuits (RFICs), feeding power to multiple antenna elements connected to the RFICs is known (see Patent Document 1). A single power divider divides the input high-frequency signal to two transmission lines so that the power is equally divided. By cascading multiple power dividers, high-frequency signals of equal power are supplied to 2ⁿ RFICs (n is a natural number).

### PRIOR ART DOCUMENT

### Patent document

[Patent Document 1] U.S. Pat. No. 6,881,675

### SUMMARY OF THE INVENTION

### Problems to be Solved

Conventional power dividers are capable of dividing high-frequency signals to 2ⁿ RFICs, but are unable to equally divide high-frequency signals to any other number of RFICs. The present disclosure is directed to providing a high-frequency power dividing circuit capable of increasing the degree of freedom in the number of targets to which a high-frequency signal input to a single node is able to be equally divided. The present disclosure is also directed to providing an antenna module using this high-frequency power dividing circuit.

### Means for Solving the Problems

According to one aspect, there is provided a high-frequency power dividing circuit, including:
a first node to which a high-frequency signal is input;
a plurality of second nodes from which high-frequency signals are output; and
a first branch transmission line connecting the first node to each of the plurality of second nodes, the first branch transmission line comprising a plurality of dividers being cascade-connected, each of the plurality of dividers having one input node and two output nodes, at least one of the plurality of dividers being equal dividers and rest of the plurality of dividers being unequal dividers with a distribution ratio of 2 or less, the first branch transmission line configured to equally divide high-frequency power input to the first node to the plurality of second nodes.

According to another aspect, there is provided an antenna module including:
above-mentioned high-frequency power dividing circuit;
a first mixer configured to up-convert a baseband signal or an intermediate frequency signal to generate an up-converted signal, input the upconverted signal to the first node, and down-convert a high-frequency signal output from the first node;
a plurality of high-frequency circuits connected to the plurality of second nodes, respectively, and having a function of amplifying a high-frequency signals output from the plurality of second nodes and outputting amplified high-frequency signals;
a plurality of antenna elements connected to the high-frequency circuits, respectively, and fed with the amplified high-frequency signals;
wherein the high-frequency circuits configured to amplify high-frequency signals received by the plurality of antenna elements to generate amplified high-frequency signals and input the amplified high-frequency signals to the plurality of second nodes, respectively.

### Advantages Effect

By configuring multiple dividers with equal dividers and unequal dividers with a division ratio of 2 or less, it is possible to increase the degree of freedom in the number of targets to which high-frequency signals are equally divided. Furthermore, by setting the division ratio of the unequal dividers to 2 or less, it is possible to suppress a decrease in isolation.

### BRIEF DESCRIPTION OF THE DRAWINGS

FIG. 1 is a schematic equivalent circuit diagram of a high-frequency power dividing circuit according to a first embodiment.

FIG. 2 is an equivalent circuit diagram of a high-frequency signal dividing circuit according to a first modification of the first embodiment.

FIG. 3A and FIG. 3B are schematic diagrams showing the normalized power values of the input nodes, the distribution ratio, and the normalized power values of the output nodes of the divider 26, and FIG. 3C is a schematic diagram showing the normalized power values of the input nodes, the distribution ratio, and the normalized power values of the output nodes of the first-stage and second-stage dividers 26A and 26B.

FIG. 4 is a schematic plan view showing an example of a wiring pattern of the divider 26.

FIG. 5 is an equivalent circuit diagram of a high-frequency power dividing circuit according to a second modification of the first embodiment.

FIG. 6 is an equivalent circuit diagram of a high-frequency power dividing circuit according to a third modification of the first embodiment.

FIG. 7 is a block diagram of an antenna module according to a second embodiment.

FIG. 8 is a schematic cross-sectional view of a portion of an antenna module according to the second embodiment.

FIG. 9 is a block diagram of an antenna module according to a third embodiment.

FIG. 10 is a schematic diagram showing the positional relationship of a plurality of components of an antenna module according to the third embodiment within the plane of a multilayer board 60.

FIG. 11 is a schematic cross-sectional view of the antenna module according to the third embodiment.

FIG. 12 is a schematic diagram showing the planar positional relationship of each component of the antenna module according to a modification of the third embodiment.

FIG. 13 is a schematic diagram showing the planar positional relationship within the plane of multilayer board 60 of multiple components of the antenna module according to a second modification of the third embodiment.

FIG. 14 is a schematic diagram showing the positional relationship within the plane of the multilayer board 60 of multiple components of a high-frequency power dividing circuit according to a fourth embodiment.

FIG. 15 is a schematic diagram showing the positional relationship within the plane of the multilayer board 60 of multiple components of a high-frequency power dividing circuit according to a comparative example.

### DETAILED DESCRIPTION

### First Embodiment

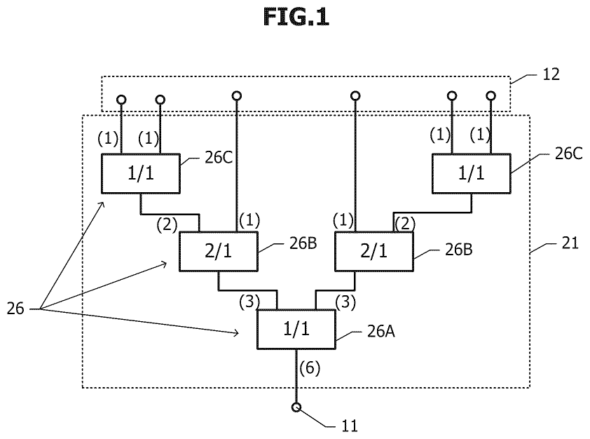

With reference to FIG. 1 through FIG. 4, a high-frequency power dividing circuit according to a first embodiment will be described.

FIG. 1 is a schematic equivalent circuit diagram of a high-frequency power dividing circuit according to the first embodiment. The high-frequency power dividing circuit according to the first embodiment includes a first node 11, multiple second nodes 12, and a first branch transmission line 21. A high-frequency signal is input to the first node 11, and a high-frequency signal is output from each of the multiple second nodes 12. The first branch transmission line 21 connects the first node 11 to each of the multiple second nodes 12, and equally divides the high-frequency signal input to the first node 11 to the multiple second nodes 12.

The first branch transmission line 21 includes multiple dividers 26 which are cascade-connected. Each of the dividers 26 divides high-frequency signals input to an input node and outputs the divided signals to two output nodes. The divider 26 is also able to function as a combiner, combining high-frequency signals input to the two output nodes and outputting the combined signal from the input node. Although the divider 26 is also able to be called a “two-signal divider/combiner,” in this specification it will be referred to as a “divider.” The node to which the undivided high-frequency signal is input and from which the combined high-frequency signal is output will be referred to as the input node. The node to which the divided high-frequency signal is output and to which the uncombined high-frequency signal is input will be referred to as the output node.

Each of the multiple dividers 26 has a distribution ratio of 2 or less. Here, “distribution ratio” is the ratio of the larger power output to the smaller power output from the two nodes of the divider. In other words, the distribution ratio of the divider 26 that divides the power of an input high-frequency signal into m and n portions (m≥n) ratio is m/n. For this reason, the distribution ratio is always 1 or greater. For example, the distribution ratio of the divider 26 that divides the power of an input high-frequency signal equally is 1, and the distribution ratio of the divider 26 that divides the power of an input high-frequency signal in 2:1 ratio is 2.

In the example shown in FIG. 1, there are six second nodes 12, and the first branch transmission line 21 equally divides the high-frequency signal input to the first node 11 to the six second nodes 12. In other words, the powers of the high-frequency signals output from the six second nodes 12 are equal. The value obtained by normalizing the power of the high-frequency signal by the power of the high-frequency signal output from each of the second nodes 12 is called the normalized power value. In other words, the normalized power value of each of the second nodes 12 is 1. In FIG. 1, the normalized power values are represented by numbers in parentheses.

The first branch transmission line 21 includes five dividers 26, and the dividers 26 are cascade-connected in a maximum of three stages. More specifically, the first branch transmission line 21 is composed of one first-stage divider 26A, two second-stage dividers 26B, and two third-stage dividers 26C.

The normalized power value of the high-frequency signal input to the first node 11 is 6. The first-stage divider 26A is an equal divider, meaning the distribution ratio is 1. As a result, a high-frequency signal with a normalized power value of 3 is output from each of the two output nodes of the divider 26A. A high-frequency signal with a normalized power value of 3 is input to each of the input nodes of the two second-stage dividers 26B. Hereinafter, the normalized power value of the high-frequency signal at the input node or the output node may simply be referred to as the normalized power value of each node.

The distribution ratio of each of the second-stage dividers 26B is 2. Therefore, the normalized power values of the two output nodes of the second-stage divider 26B are 2 and 1. The output node with a normalized power value of 1 is connected directly to the second node 12. The output node with a normalized power value of 2 is connected to the input node of the third-stage divider 26C.

Each of the third-stage dividers 26C is an equal divider. Therefore, the normalized power value of each of the two output nodes of the third-stage divider 26C is 1. The output nodes with a normalized power value of 1 are connected directly to the second nodes 12, respectively. In this way, the first branch transmission line 21 shown in FIG. 1 equally divides the high-frequency signal input to the first node 11 to the six second nodes 12. The five dividers 26 includes equal dividers and unequal dividers with a division ratio of 2 or less.

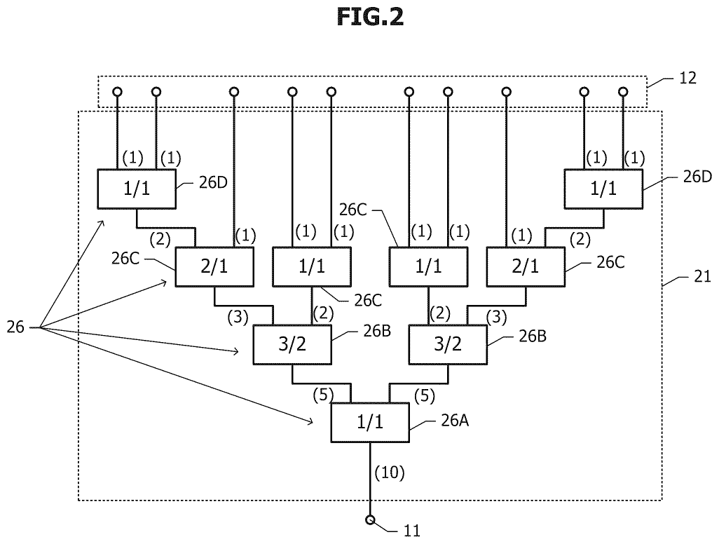

FIG. 2 is an equivalent circuit diagram of a high-frequency signal dividing circuit according to a first modification of the first embodiment. In the first modification shown in FIG. 2, there are ten second nodes 12. The first branch transmission line 21 is composed of nine dividers 26, and the multiple dividers 26 are cascade-connected in a maximum of four stages. The normalized power value of the first node 11 is 10.

The first-stage divider 26A is an equal divider. Therefore, the normalized power value of each of the two output nodes of the first-stage divider 26A is 5. The distribution ratios of the two second-stage dividers 26B are both 3/2. Therefore, the normalized power values of the two output nodes of the second-stage divider 26B are 3 and 2, respectively.

The input node of the third-stage divider 26C, whose distribution ratio is 2, is connected to the output node with a normalized power value of 3, and the input node of the third-stage divider 26C, whose distribution ratio is 1, is connected to the output node with a normalized power value of 2.

The normalized power values of the two output nodes of the divider 26C, which has a distribution ratio of 2, are 2 and 1. The normalized power values of the two output nodes of the divider 26C, which has a distribution ratio of 1, are both 1. The output nodes with normalized power values of 2 are respectively connected to the input nodes of the fourth-stage dividers 26D, which has a distribution ratio of 1. The normalized power values of the two output nodes of each of the fourth-stage dividers 26D are both 1. The output nodes with normalized power values of 1 are connected directly to the second nodes 12, respectively.

In the first modification shown in FIG. 2, the distribution ratio of each of the two dividers 26B in the second stage is 3/2, and the distribution ratio of each of the two dividers 26C of the four dividers 26C in the third stage is 2. The other dividers 26 are equal dividers. In this way, the distribution ratio of each of the nine dividers 26 is 2 or less, and the first branch transmission line 21 includes four dividers 26 (unequal dividers) with a division ratio other than 1.

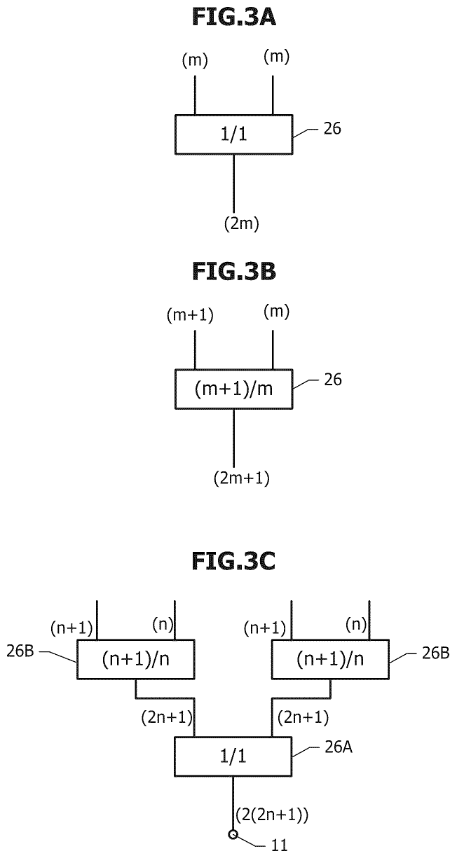

Next, the function of the divider 26 will be explained with reference to FIG. 3A, FIG. 3B, and FIG. 3C. FIG. 3A and FIG. 3B are schematic diagrams showing the normalized power values of the input nodes of the divider 26, the distribution ratio, and the normalized power values of the output nodes of the divider 26.

As shown in FIG. 3A, for a divider 26 whose input node has a normalized power value that is an even number (2m), the distribution ratio is set to 1. Here, the parameter m is a natural number, that is, an equal divider is used as the divider 26. In this case, the normalized power values of the two output nodes of the divider 26 are both m. As shown in FIG. 3B, for a divider 26 whose input node has a normalized power value that is an odd number (2m+1), the distribution ratio is set to (m+1)/m. In other words, an unequal divider with a distribution ratio of 2 or less is used as the divider 26. More specifically, this unequal divider divides power so that the difference between the normalized power values after division is 1. In this case, the normalized power values of the two output nodes of the divider 26 are (m+1) and m. When the normalized power value of an output node becomes 1, that output node is directly connected to the second node 12.

FIG. 3C is a schematic diagram showing the normalized power values of the input nodes, distribution ratios and the normalized power values of the output nodes, of the first-stage and second-stage dividers 26A and 26B. An example will be described in which the normalized power value of the first node 11 is 2×(2n+1). Here, the parameter n is a natural number. When n=1, the first branch transmission line 21 has the configuration shown in FIG. 1, and when n=2, the first branch transmission line 21 has the configuration shown in FIG. 2.

As for the first-stage divider 26A, since the normalized power value of the input node is an even number, the division ratio is 1. The normalized power values of the two output nodes of the first-stage divider 26A are both (2n+1). Since the normalized power value of the input node of each of the second-stage dividers 26B is an odd number, the distribution ratio is (n+1)/n. Therefore, the normalized power values of the two output nodes of each of the second-stage dividers 26B are (n+1) and n. For the dividers 26 in the third stage and subsequent stages, the dividers 26 shown in FIG. 3A or FIG. 3B are used.

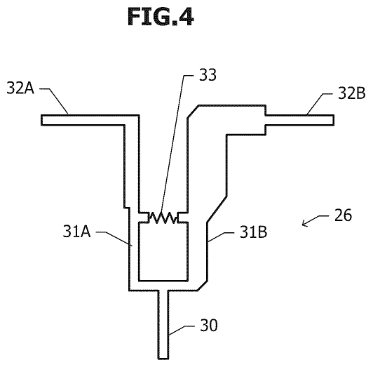

FIG. 4 is a schematic plan view showing an example of the wiring pattern of the divider 26. The wiring pattern is formed on a dielectric board. An input transmission line 30 branches into a pair of input branch transmission lines 31A and 31B and a pair of output branched transmission lines 32A and 32B are connected to the output ends of the pair of the branch transmission lines 31A and 31B, respectively. A resistor 33 is connected between the midpoint of a first input branch transmission line 31A and the midpoint of a second branch transmission line 31B. A surface-mount resistor, for example, is used as the resistor 33. This type of divider 26 is called a Wilkinson-type power divider.

The distribution ratio of the divider 26 is able to be adjusted by changing the ratio of the characteristic impedances of the branch transmission lines 31A and 31B. The characteristic impedances of the branch transmission lines 31A and 31B are able to be adjusted by changing the line width of the strip line or microstrip line. For example, when the ratio of the characteristic impedances of the pair of input branch transmission lines 31A and 31B is approximately 2.5, the distribution ratio is approximately 2. In order to set the distribution ratio of the divider 26 to 2 or less, the ratio of the characteristic impedances of the pair of input branch transmission lines 31A and 31B may be set to 2.5 or less.

Varying the ratio of the line widths of the pair of input branch transmission lines 31A and 31B changes the ratio of their characteristic impedances. As shown in FIG. 4, the line widths of the pair of input branch transmission lines 31A and 31B may be changed in the middle thereof. In this case, the ratio of the line width of the thickest part of the relatively thick branch transmission line 31B to the line width of the thinnest part of the relatively thin branch transmission line 31A may be defined as the line width ratio of the pair of input branch transmission lines 31A and 31B.

The characteristic impedance of the branch source transmission line 30 is equal to the characteristic impedance of each of the pair of output branched transmission lines 32A and 32B. In other words, the line width of the branch source transmission line 30 is equal to the line width of each of the pair of output branched transmission lines 32A and 32B.

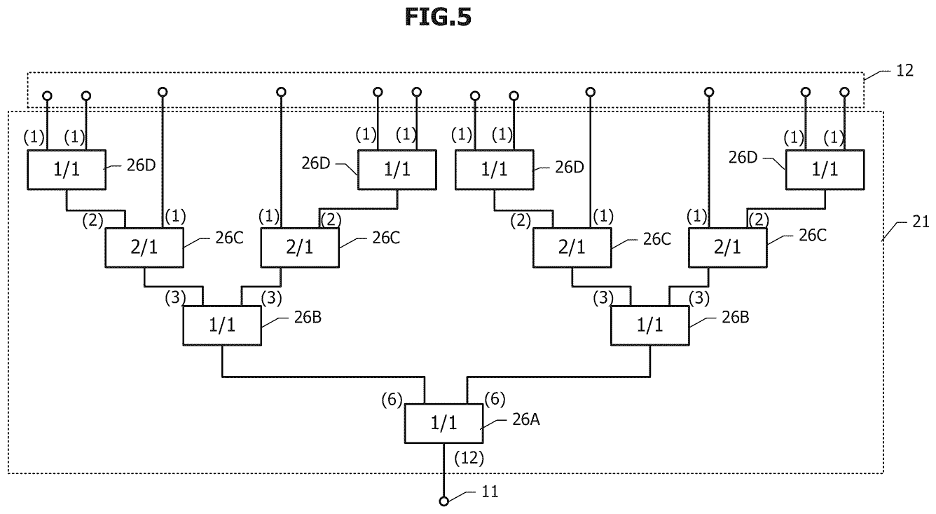

Next, a high-frequency power dividing circuit according to a second modification of the first embodiment will be described with reference to FIG. 5. FIG. 5 is an equivalent circuit diagram of the high-frequency power dividing circuit according to the second modification of the first embodiment.

In the first embodiment (FIG. 1) and the first modification of the first embodiment (FIG. 2), the number of second nodes 12 is 2×(2n+1). Here, the parameter n is a natural number. That is, the normalized power value of the first node 11 is 2×(2n+1). Because the normalized power value of the input node of the first-stage divider 26A is an even number, a divider 26 (FIG. 3A) with a distribution ratio of 1 is used as the first-stage divider 26A. Because the normalized power value of the input node of each of the second-stage divider 26B is an odd number, a divider 26 (FIG. 3B) with a distribution ratio of (m+1)/m is used as each of the second-stage dividers 26B.

In contrast, in the second modification shown in FIG. 5, the number of second nodes 12 is a multiple of 4, for example 12. In this case, the normalized power values of the two output nodes of the first-stage divider 26, which has a distribution ratio of 1, are also even numbers. For example, the normalized power value of the output node of the first-stage divider 26 is 12, and the normalized power values of the two output nodes are both 6.

Therefore, a divider 26 (FIG. 3A) with a distribution ratio of 1 is also used for each of the second-stage dividers 26B. The connection configuration of the dividers 26 from each of the two second-stage dividers 26B to the fourth-stage dividers 26D is the same as the connection configuration of the dividers 26 of the first branch transmission line 21 shown in FIG. 1.

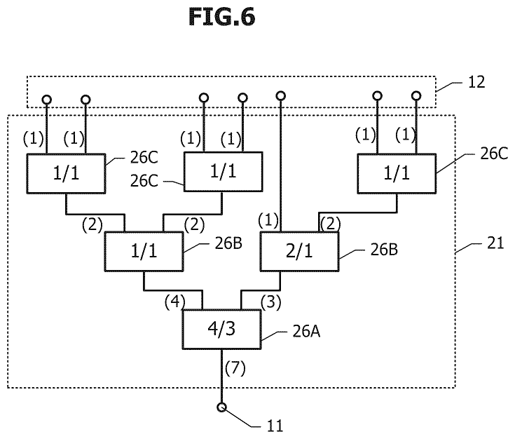

Next, a high-frequency power dividing circuit according to a third modification of the first embodiment will be described with reference to FIG. 6. FIG. 6 is an equivalent circuit diagram of the high-frequency power dividing circuit according to the third modification of the first embodiment. In the first embodiment (FIG. 1), the first modification of the first embodiment (FIG. 2), and the second modification of the first embodiment (FIG. 5), the number of second nodes 12 is an even number. In contrast, in the third modification of the first embodiment, the number of second nodes 12 is an odd number. FIG. 6 shows an example in which the number of second nodes 12 is seven.

Because the number of second nodes 12 is odd, the normalized power value of the input node of the first-stage divider 26A is also odd, for example, 7. One of the two output nodes of the first-stage divider 26A has an even normalized power value, for example, 4, and the other output node has an odd normalized power value, for example, 3. A divider 26 (FIG. 3A) with a distribution ratio of 1 may be connected to the output node with an even normalized power value, and a divider 26 (FIG. 3B) with a distribution ratio of (m+1)/m may be connected to the output node with an odd normalized power value.

From the third stage and subsequent stages, by combining a divider 26 (FIG. 3A) with a distribution ratio of 1 with a divider 26 (FIG. 3B) with a distribution ratio of (m+1)/m, the normalized power value of all output nodes of the divider 26 could be made 1. Note that in the example shown in FIG. 6, only the dividers 26 (FIG. 3A) with a distribution ratio of 1 are used as dividers 26 in the third stage and subsequent stages.

Next, the advantageous effects of the first embodiment and its modifications will be explained.

In the first embodiment, by using not only a divider that divides power equally but also at least one divider 26 (unequal divider) that is not an equal divider, it is possible to equally divide high-frequency signals to the multiple second nodes 12 even when the number of the second nodes 12 is other than 2ⁿ (n is a natural number). Dividers with large distribution ratios are difficult to implement on a multilayer board. In the first embodiment, the power distribution ratio of each of the multiple dividers 26 is 2 or less, so that they could be easily implemented on the multilayer board. Furthermore, by setting the distribution ratio to 2 or less, it is easy to configure a divider 26 with high isolation.

In the first embodiment, a divider 26 with a distribution ratio of 1 (FIG. 3A) and a divider 26 with a distribution ratio of (m+1)/m (FIG. 3B) are used. However, when a high-frequency signal dividing circuit is used to feed power to antenna elements, the distribution ratio may deviate from the target value within a range allowable in terms of the operation of the multiple antenna elements. For example, even if the distribution ratio of a divider 26 is not exactly 1, and the distribution ratio deviates from the target value within the allowable error range defined in the specification of the divider 26, the divider 26 can be treated as an equal divider. In this case, a divider 26 with a distribution ratio greater than 1.1 and equal to or less than 2 may be treated as a “divider 26 (unequal divider) that is not an equal divider” included in the first branch transmission line 21.

### Second Embodiment

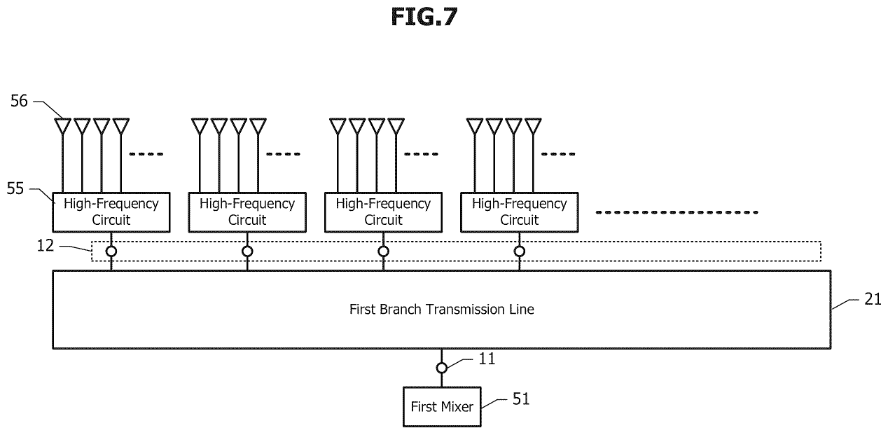

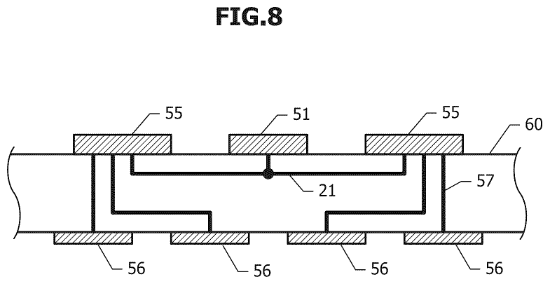

Next, an antenna module according to a second embodiment will be described with reference to FIG. 7 and FIG. 8. Hereinafter, description of the constitutions common to the first embodiment and its modifications described with reference to FIG. 1 through FIG. 6 will be omitted.

FIG. 7 is a block diagram of an antenna module according to the second embodiment. The antenna module according to the second embodiment includes a high-frequency power dividing circuit consisting of a first node 11, multiple second nodes 12, and a first branch transmission line 21. As this high-frequency power dividing circuit, the high-frequency power dividing circuit according to one of the first embodiment and its modifications is used.

A first mixer 51 is connected to the first node 11. The first mixer 51 upconverts a baseband signal or an intermediate frequency signal and inputs an upconverted signal to the first node 11. Furthermore, the first mixer 51 has the function of down-converting a high-frequency signal output from the first node 11 to a baseband signal or an intermediate frequency signal. High-frequency circuits 55 (RFIC) are respectively connected to the multiple second nodes 12. Each of the high-frequency circuits 55 has multiple antenna terminals and has the function of amplifying the high-frequency signal output from the second node 12 and outputting the amplified signal from each of the multiple antenna terminals. The power values of the high-frequency signals output from the multiple antenna terminals are equal.

Multiple antenna elements 56 are respectively connected to the antenna terminals of the multiple high-frequency circuits 55. High-frequency signals amplified by the high-frequency circuits 55 are supplied to the multiple antenna elements 56, respectively. Furthermore, the high-frequency signals received by the multiple antenna elements 56 are respectively input to the antenna terminals of the high-frequency circuits 55. Each of the high-frequency circuits 55 has the function of combining the high-frequency signals input to the multiple antenna terminals, amplifying the combined signal, and inputting the amplified signal to the second node 12. The high-frequency circuit 55 adjusts the phase of the high-frequency signals supplied to the multiple antenna elements 56, causing the multiple antenna elements 56 to operate as a phased array antenna. The high-frequency circuit 55 with this function is called a beamforming IC (BFIC) in some cases.

FIG. 8 is a schematic cross-sectional view of a portion of the antenna module according to the second embodiment. The first mixer 51 and the multiple high-frequency circuits 55 are mounted on one surface of a multilayer board 60. The multiple antenna elements 56 are formed on the other surface of the multilayer board 60. Each of the multiple antenna elements 56 is, for example, a patch antenna.

The first mixer 51 is connected to the multiple high-frequency circuits 55 via a first branch transmission line 21, which includes a strip line or microstrip line arranged within a multilayer board 60. The multiple high-frequency circuits 55 are respectively connected to the antenna elements 56 via feeder lines 57 provided on or within the multilayer board 60.

Next, the advantageous effects of the second embodiment will be explained.

In the second embodiment, the first branch transmission line 21 is the same as that of the first embodiment or the modifications thereof, so the high-frequency signal output from the first mixer 51 is equally divided to the multiple high-frequency circuits 55. This makes it possible to prevent the directivity pattern from deviating from symmetrical shape. Furthermore, even if the number of high-frequency circuits 55 is other than 2ⁿ (n is a natural number), the high-frequency signal could be equally divided to the multiple high-frequency circuits 55. Furthermore, as in the first embodiment, the antenna module could be easily mounted on the multilayer board, and high isolation could be easily ensured.

### Third Embodiment

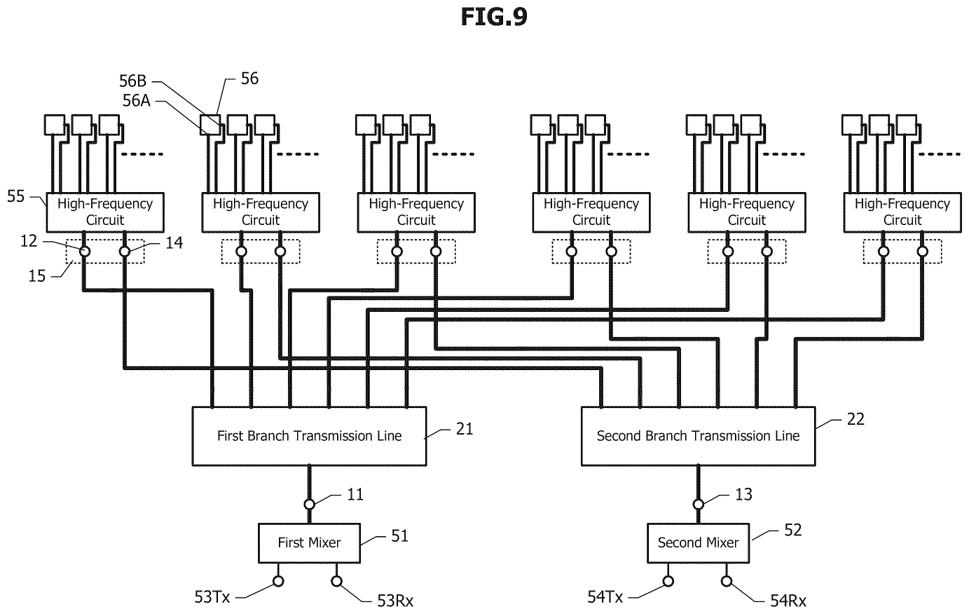

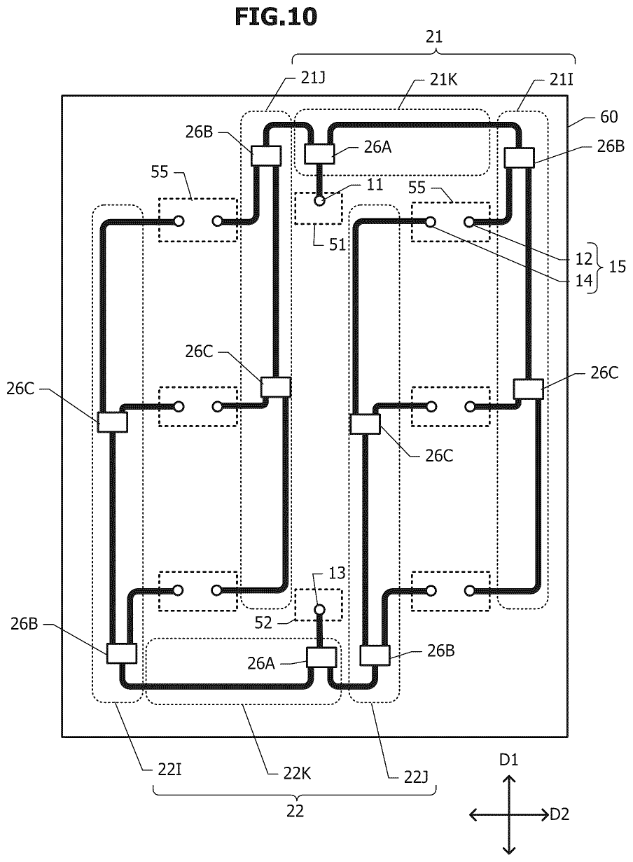

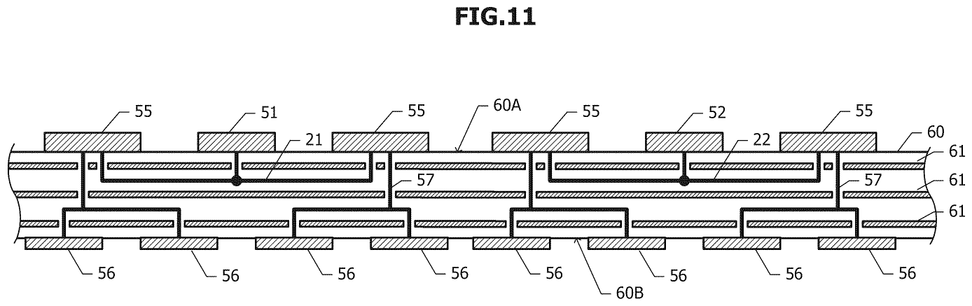

Next, an antenna module according to a third embodiment will be described with reference to FIG. 9, FIG. 10, and FIG. 11. Hereinafter, description of constitutions common to the antenna module according to the second embodiment will be omitted.

FIG. 9 is a block diagram of the antenna module according to the third embodiment. In addition to the components of the antenna module according to the second embodiment, the antenna module according to the third embodiment includes a third node 13, a second branch transmission line 22, multiple fourth nodes 14, and a second mixer 52. The configurations of the third node 13, the second branch transmission line 22, the multiple fourth nodes 14, and the second mixer 52 are identical to the configurations of the first node 11, the first branch transmission line 21, the multiple second nodes 12, and the first mixer 51 of the antenna module according to the second embodiment (FIG. 7).

In other words, a high-frequency signal is input from the second mixer 52 to the third node 13. The high-frequency signal input to the third node 13 is equally divided and output from the multiple fourth nodes 14. The number of fourth nodes 14 is the same as the number of second nodes 12. Each of the multiple second nodes 12 and each of the multiple fourth nodes 14 constitutes one node pair 15. The second branch transmission line 22 is formed on or within the same multilayer board 60 (FIG. 8) on or within which the first branch transmission line 21 is formed, and the second mixer 52 is mounted on the same multilayer board 60 on which the first mixer 51 is mounted.

A first transmitting terminal 53Tx and a first receiving terminal 53Rx for connecting to an external circuit are connected to the first mixer 51. When a transmitting signal is input from the external circuit to the first transmitting terminal 53Tx, the transmitting signal is upconverted by the first mixer 51, and the upconverted high-frequency signal is equally divided to the second nodes 12 by the first branch transmission line 21. The high-frequency signals equally divided to the second nodes 12 are radiated from the antenna elements 56 via the high-frequency circuits 55.

High-frequency signals received by the antenna elements 56 are input to the second nodes 12 via the high-frequency circuits 55. The high-frequency signals input to the second nodes 12 are combined by the first branch transmission line 21. The combined high-frequency signal is down-converted by the first mixer 51. The down-converted baseband signal or intermediate frequency signal is output from the first receiving terminal 53Rx.

Similarly, a second transmitting terminal 54Tx and a second receiving terminal 54Rx for connecting to the external circuit are connected to the second mixer 52. Similarly to the operation of the first branch transmission line 21, when a transmitting signal is input to the second transmitting terminal 54Tx, the up-converted high-frequency signal is equally divided to the fourth nodes 14. When high-frequency signals received by the antenna elements 56 are input to the fourth nodes 14, the high-frequency signals are combined, then down-converted, and output from the second receiving terminal 54Rx.

The first transmitting terminal 53Tx and the first receiving terminal 53Rx may be combined into a single first terminal for transmitting and receiving. Furthermore, the second transmitting terminal 54Tx and the second receiving terminal 54Rx may be combined into a single second terminal for transmitting and receiving. In this case, for example, switches within the high-frequency circuits 55 may be used to switch between transmitting and receiving operations.

One high-frequency circuit 55 is connected to each of the multiple node pairs 15. For example, a single common high-frequency circuit 55 is connected to the second node 12 and the fourth node 14 of each of the multiple node pairs 15. Multiple antenna elements 56 are connected to each of the multiple high-frequency circuits 55. Each of the multiple high-frequency circuits 55 separately amplifies the high-frequency signal input from the second node 12 and the high-frequency signal input from the fourth node 14, outputs them separately from the different output terminals, and supplies them to the multiple antenna elements 56. For example, the numbers of antenna elements 56 connected to the respective high-frequency circuits 55 are equal among the multiple high-frequency circuits 55.

Each of the multiple antenna elements 56 has a first feed point 56A to which an amplified high-frequency signal input from the second node 12 is input, and a second feed point 56B to which an amplified high-frequency signal input from the fourth node 14 is input. When power is supplied to the first feed point 56A and when power is supplied to the second feed point 56B, each of the multiple antenna elements 56 radiates mutually orthogonal polarized waves, for example, vertically polarized wave and horizontally polarized wave. Furthermore, the polarized wave when power is supplied to the first feed point 56A is the same among the multiple antenna elements 56, and the polarized wave when power is supplied to the second feed point 56B is also the same among the multiple antenna elements 56.

By supplying the high-frequency signal output from the first mixer 51 to the first feed point 56A of each of the multiple antenna elements 56, it is possible to radiate radio waves of the same polarization from the multiple antenna elements 56. Furthermore, by supplying the high-frequency signal output from the second mixer 52 to the second feed point 56B of each of the multiple antenna elements 56, it is possible to radiate radio waves from the multiple antenna elements 56 that are polarized orthogonally to the polarized waves radiated when the first mixer 51 is operated.

Furthermore, two radio waves having mutually orthogonal polarizations could be received by the first mixer 51 and the second mixer 52, respectively. By controlling the phases of the high-frequency signals supplied to the multiple antenna elements 56, the multiple antenna elements 56 could be operated as a phased array antenna.

FIG. 10 is a schematic diagram showing the positional relationship in a plan view of the multilayer board 60, of multiple components of the antenna module according to the third embodiment. A first direction D1 parallel to the surface of the multilayer board 60 and a second direction D2 intersecting the first direction are defined. For example, the first direction D1 and the second direction D2 are mutually orthogonal. FIG. 10 shows an example in which the number of node pairs 15 is an even number, such as six. That is, the number of second nodes 12 and the number of fourth nodes 14 are also even numbers, such as six.

The multiple node pairs 15 are arranged in two columns in the first direction D1 on or within the multilayer board 60. For example, six node pairs 15 are arranged in a matrix of three rows and two columns. The multiple node pairs 15 aligned in the first direction D1 are referred to as a node pair column. In each of the multiple node pairs 15, the second node 12 and the fourth node 14 are aligned in the second direction D2 and are arranged in the same positional relationship with respect to the second direction D2. In other words, the distance between the second node 12 and the fourth node 14 is equal among the multiple node pairs 15.

The first branch transmission line 21 includes two first portions 21I and 21J, and a first connection portion 21K. The first portions 21I and 21J are arranged along the two node pair columns, on the first side (right side in FIG. 10) of each of the two node pair columns with respect to the second direction D2. The first connection portion 21K connects the two first portions 21I and 21J at a location that does not overlap with the two node pair columns with respect to the first direction D1. In this way, the first branch transmission line 21 is arranged within a U-shaped region in a plan view (a U-shaped region that opens downward in FIG. 10). Furthermore, the first connection portion 21K is connected to the first node 11.

The first connection portion 21K includes the first-stage divider 26A, and each of the two first portions 21I and 21J includes the second-stage divider 26B and the third-stage divider 26C.

Like the first branch transmission line 21, the second branch transmission line 22 also includes two second portions 22I and 22J, and a second connection portion 22K. The second portions 22I and 22J are arranged along the two node pair columns on the second side (left side in FIG. 10) opposite to the first side of each of the two node pair columns with respect to the second direction D2. The second connection portion 22K connects the two second portions 22I and 22J at a location that does not overlap with the two node pair columns with respect to the first direction D1. Furthermore, the second connection portion 22K is connected to the third node 13.

In the second branch transmission line 22, the second connection portion 22K also includes the first-stage divider 26A, and each of the two second portions 22I and 22J includes the second-stage divider 26B and the third-stage divider 26C.

The first connection portion 21K and the second connection portion 22K are arranged so as to sandwich two node pair columns in the first direction D1. For example, the second branch transmission line 22 is arranged in a U-shaped region in a plan view (a U-shaped region that opens upward in FIG. 10). The U-shaped region within which the first branch transmission line 21 is arranged and the U-shaped region within which the second branch transmission line 22 is arranged have a mutually interdigitating positional relationship. In a plan view, the conductor pattern constituting the first branch transmission line 21 and the conductor pattern constituting the second branch transmission line 22 are two-fold rotationally symmetric with each other. That is, the first node 11 of the first branch transmission line 21 and the third node 13 of the second branch transmission line 22 are located on opposite sides of each other when viewed from the rotation center of the two-fold rotational symmetry.

In a plan view, the high-frequency circuits 55 are arranged so as to overlap the respective multiple node pairs 15, the first mixer 51 is arranged so as to overlap the first node 11, and the second mixer 52 is arranged so as to overlap the third node 13. Therefore, the six high-frequency circuits 55, like the six node pairs 15, are aligned in two columns in the first direction D1.

FIG. 11 is a schematic cross-sectional view of an antenna module according to the third embodiment. FIG. 11 does not show a specific cross-section of the antenna module, but rather shows multiple components of the antenna module, focusing on their positional relationships in the thickness direction.

The first mixer 51, the second mixer 52, and the high-frequency circuits 55 are mounted on one surface (hereinafter referred to as the first surface 60A) of the multilayer board 60. The antenna elements 56 are placed on a second surface 60B of the multilayer board 60, opposite to the first surface 60A. The multilayer board 60 has a multilayer wiring structure, and the first branch transmission line 21, the second branch transmission line 22, feeder lines 57, and ground conductors 61 are arranged on the inner layers of the multilayer board 60.

The first mixer 51 is connected to the high-frequency circuits 55 via the first branch transmission line 21, and the second mixer 52 is connected to the high-frequency circuits 55 via the second branch transmission line 22.

The first branch transmission line 21 and the second branch transmission line 22 include conductor patterns arranged on inner layers of the multilayer board 60. These conductor patterns and the ground conductors 61 form a stripline. The conductor patterns included in the first branch transmission line 21 and the second branch transmission line 22 are arranged on the same single layer. Because the conductor patterns included in the first branch transmission line 21 and the second branch transmission line 22 are two-fold rotationally symmetric with each other in a plan view, it is possible to arrange both on the same single layer. In the example shown in FIG. 11, the conductor patterns included in the first branch transmission line 21 and the second branch transmission line 22 are arranged on the second wiring layer between the first ground conductor 61 and the third ground conductor 61, counting from the first surface 60A.

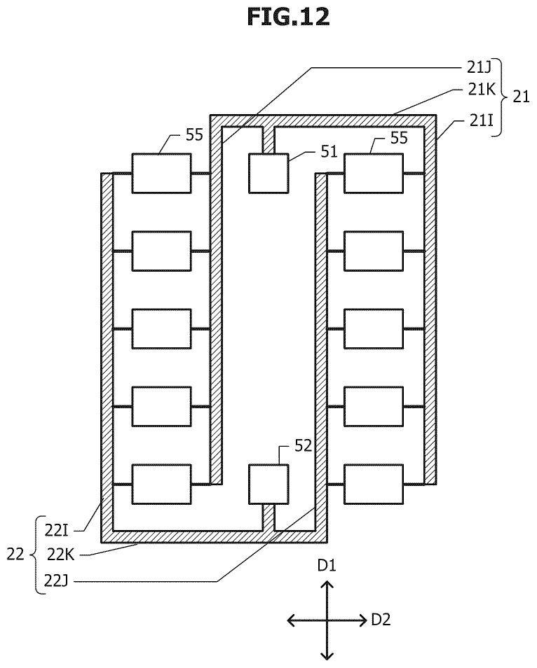

Next, an antenna module according to a first modification of the third embodiment will be described with reference to FIG. 12. FIG. 12 is a schematic diagram showing the planar positional relationship of components of the antenna module according to the first modification of the third embodiment. While the third embodiment (FIG. 10) has six high-frequency circuits 55, the first modification has ten high-frequency circuits 55. The ten high-frequency circuits 55 are arranged in two columns in the first direction D1. Each of the two columns includes five high-frequency circuits 55.

As in the third embodiment (FIG. 10), the first branch transmission line 21 includes two first portions 21I and 21J, and a first connection portion 21K connecting the two first portions 21I and 21J. The second branch transmission line 22 includes two second portions 22I and 22J, and a second connection portion 22K connecting the two second portions 22I and 22J. The U-shaped region within which the first branch transmission line 21 is located and the U-shaped region within which the second branch transmission line 22 is located are arranged so that they interdigitate with each other. In FIG. 12, the U-shaped region within which the first branch transmission line 21 is located and the U-shaped region within which the second branch transmission line 22 is located are hatched.

Next, the advantageous effects of the third embodiment will be explained.

In the third embodiment, the high-frequency signals output from the first mixer 51 and the second mixer 52 are equally divided to the multiple high-frequency circuits 55. Furthermore, even when the number of high-frequency circuits 55 is other than 2ⁿ (n is a natural number), the high-frequency signals could be equally divided to the multiple high-frequency circuits 55. Furthermore, as in the first embodiment, the antenna module could be easily mounted on a multilayer board, and high isolation could be easily ensured. Furthermore, it is possible to deal with two mutually orthogonal polarized waves.

Furthermore, by arranging the first branch transmission line 21 and the second branch transmission line 22 in mutually interdigitating U-shaped regions, respectively, the wiring length could be shortened, which is an advantageous effect. This makes it possible to suppress an increase in transmission loss.

In the third embodiment, the first mixer 51 and the second mixer 52 are connected to the first transmitting terminal 53Tx and the second transmitting terminal 54Tx, respectively. Therefore, two transmitting signals, encoding different pieces of information respectively, could be input to the first mixer 51 and the second mixer 52, and transmitted from the antenna elements 56. The transmitting signal input to the first mixer 51 and the transmitting signal input to the second mixer 52 are radiated from the antenna elements 56 with mutually orthogonal polarizations. This provides the advantageous effect of doubling the amount of information to be transmitted.

Furthermore, when receiving mutually orthogonal polarized waves, the received signal based on one polarized wave is output from the first receiving terminal 53Rx connected to the first mixer 51, and the received signal based on the other polarized wave is output from the second receiving terminal 54Rx connected to the second mixer 52. This provides the advantageous effect of doubling the amount of information to be received.

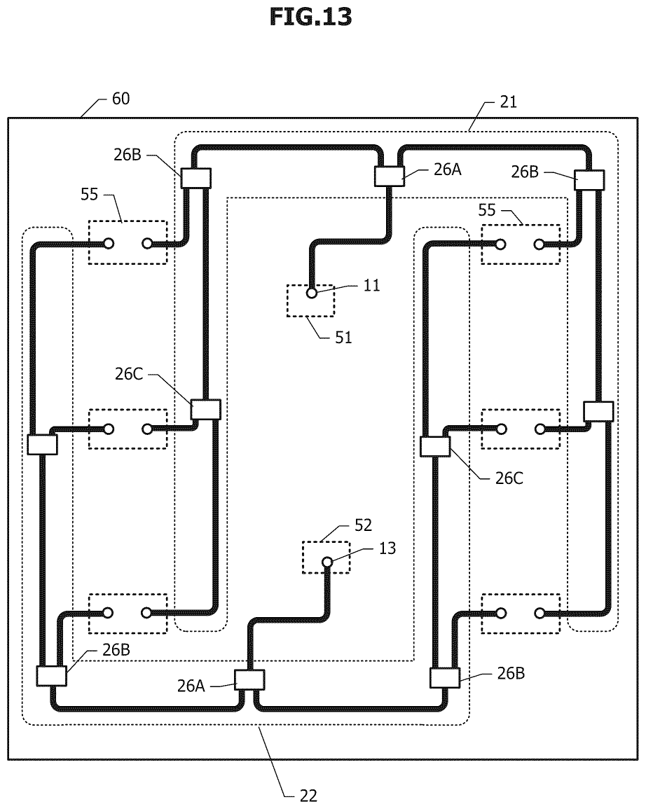

Next, an antenna module according to a second modification of the third embodiment will be described with reference to FIG. 13. FIG. 13 is a schematic diagram showing the positional relationship in a plan view of the multilayer bord 60 of multiple components of the antenna module according to the second modification of the third embodiment. In the antenna module according to the third embodiment (FIG. 10), the two transmission lines extending from the two output nodes of the first-stage divider 26A to the input nodes of the two second-stage dividers 26B have different line lengths.

In contrast, in the antenna module according to the second modification shown in FIG. 13, the line lengths of the two transmission lines extending from the two output nodes of the first-stage divider 26A to the respective input nodes of the two second-stage dividers 26B are equal.

The first-stage divider 26A is an equal divider. Therefore, the powers of the high-frequency signals output from the two output nodes of the first-stage divider 26A are equal. In the third embodiment (FIG. 10), if a difference in transmission loss occurs due to a difference in line length, a difference in the power of the high-frequency signals input to the two second-stage dividers 26B may occur. In the second modification of the third embodiment, the line lengths of the two transmission lines extending from the two output nodes of the first-stage divider 26A to the respective input nodes of the two second-stage dividers 26B are equal. Therefore, a difference in transmission loss is unlikely to occur. As a result, a difference in the power of the high-frequency signals input to the two second-stage dividers 26B is unlikely to occur.

Next, an antenna module according to another modification of the third embodiment.

In the third embodiment (FIG. 10), the first mixer 51 and the second mixer 52 corresponding to the first branch transmission line 21 and the second branch transmission line 22, respectively, are located in separate locations. However, the first mixer 51 and the second mixer 52 may also be configured in one chip and located in one location.

### Fourth Embodiment

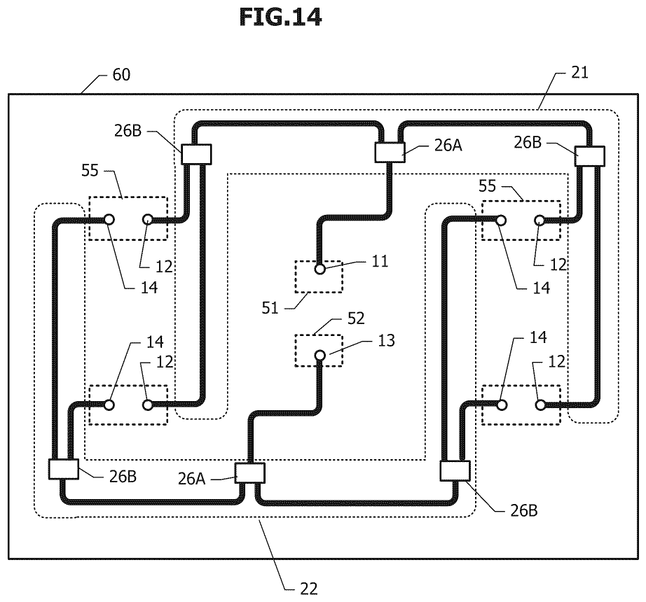

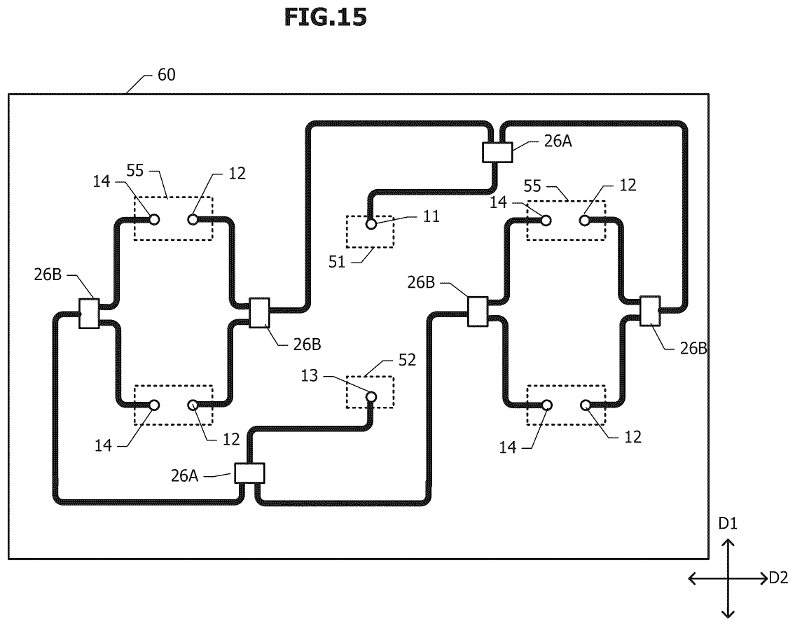

Next, a high-frequency power dividing circuit according to the fourth embodiment will be described with reference to FIG. 14 and FIG. 15. Hereinafter, description of the configurations common to the high-frequency power dividing circuit used in the antenna module according to the third embodiment described with reference to FIG. 9 through FIG. 11 will be omitted.

FIG. 14 is a schematic diagram showing the positional relationship in a plan view of the multilayer board 60 of multiple components of the high-frequency power dividing circuit according to the fourth embodiment. In the third embodiment (FIG. 10), the number of the second nodes 12 of the first branch transmission line 21 and the number of the fourth nodes 24 of the second branch transmission line 22 are both six. That is, the number of the second nodes 12 and the number of the fourth nodes 14 are not expressed as a power of two. In contrast, the number of the second nodes 12 of the first branch transmission line 21 and the number of the fourth nodes 14 of the second branch transmission line 22 of the high-frequency power dividing circuit according to the fourth embodiment are both four. That is, the number of the second nodes 12 and the number of the fourth nodes 14 are both expressed as a power of two.

The two output nodes of each of the second-stage divider 26B are connected to the respective second nodes 12. The divider 26B whose two output nodes are connected to the respective second nodes 12 is referred to as the final-stage divider. If the number of the second nodes 12 in the first branch transmission line 21 is four, then the number of the final-stage dividers 26B is two. Similarly, the number of the final-stage dividers 26B in the second branch transmission line 22 is also two.

The first branch transmission line 21 includes two transmission lines having different line lengths that connect the two output nodes to the respective two second nodes 12, for each final-stage divider 26B. Similarly, the second branch transmission line 22 includes two transmission lines having different line lengths that connect the two output nodes to the respective two fourth nodes 14, for each final-stage divider 26B.

Generally, differences in transmission loss occur when the line lengths of the transmission lines differ. The final-stage divider 26B has a distribution ratio configured to equalize the powers of the high-frequency signals at the two second nodes 12, even when taking into account the losses of the two transmission lines connected to the two output nodes. For example, the final-stage divider 26B divides power such that the output node connected to the transmission line with the longer line length outputs more power than the other output node. In order to compensate for difference in transmission loss due to difference in the line lengths of the transmission lines, it is sufficient to set the distribution ratio of the final-stage divider 26B to a range of 2 or less.

The transmission lines from the first-stage divider 26A to the two second-stage dividers 26B have the same line length. Therefore, even when considering transmission loss due to the transmission line, the powers of the high-frequency signals input to the two second-stage dividers 26B are equal. Therefore, the first branch transmission line 21 could divide power equally to the four second nodes 12. Similarly, the second branch transmission line 22 could divide power equally to the four fourth nodes 14.

Next, the advantageous effects of the fourth embodiment will be described in comparison with to the high-frequency power dividing circuit according to a comparative example shown in FIG. 15.

FIG. 15 is a schematic diagram showing the positional relationship of multiple components of the high-frequency power dividing circuit in a plan view of a multilayer board 60 according to the comparative example. In the comparative example shown in FIG. 15, equal dividers are used as the second-stage dividers 26B. In order to equalize the powers of the high-frequency signals supplied to the two second nodes 12 connected to the two output nodes of the second-stage divider 26B, the line lengths of the two transmission lines connected to the two output nodes are made equal.

In the comparative example, the divider 26B must be positioned such that the two transmission lines extending from the two output nodes of the divider 26B to the two second nodes 12 are equal in length. This limits the arrangement flexibility of the divider 26. This makes it difficult to shorten the length of the transmission lines extending from the first-stage divider 26A to the two second-stage dividers 26.

In contrast, in the fourth embodiment, the line lengths of the two transmission lines extending from the two output nodes of the divider 26B to the respective two second nodes 12 do not need to be equal, which increases the degree of flexibility in arranging the divider 26B. As a result, it is possible to determine the positions of the two second-stage dividers 26B such that the line lengths of the transmission lines extending from the first-stage divider 26A to the respective two second-stage dividers 26B are short.

As described above, in the fourth embodiment, the second-stage divider 26B could be positioned such that the total line length of the transmission lines is shortened. As a result, overall transmission loss could be suppressed. In this way, a configuration in which the first branch transmission line 21 and the second branch transmission line 22 include unequal dividers with a distribution ratio of 2 or less has advantageous effects not only when the number of second nodes 12 is not expressed as a power of 2, but also when it is expressed as a power of 2.

Next, a high-frequency power dividing circuit according to a modification of the fourth embodiment will be described.

In the high-frequency power dividing circuit according to the fourth embodiment, each of the first branch transmission line 21 and the second branch transmission line 22 is a dividing circuit with a two-stage structure. A structure similar to that of the fourth embodiment could also be adopted even when each of the first branch transmission line 21 and the second branch transmission line 22 are structured in three or more stages. For example, if the first branch transmission line 21 had a three-stage structure, the number of second nodes 12 would be eight, and each of the four dividers in the third stage would be the final-stage divider.

In the fourth embodiment, the distribution ratio of the final-stage divider 26B is set such that the powers of the high-frequency signals output from the two second nodes 12 connected to the respective two output nodes of the final-stage divider 26B are equal, but it is not necessary for the powers of the high-frequency signals output from the two second nodes 12 to be strictly equal. For example, the distribution ratio of the final-stage divider 26B may be set such that the difference in power between the high-frequency signals at the two second nodes 12 connected to the final-stage divider 26B is smaller than the difference in power between the high-frequency signals when an equal divider is used as the final-stage divider 26B.

The above-described embodiments are merely illustrative, and it goes without saying that partial substitution or combination of the features shown in different embodiments is possible. Similar advantageous effects resulting from similar features in multiple embodiments will not be mentioned sequentially for each embodiment. Furthermore, the present invention is not limited to the above-described embodiments. For example, it will be obvious to those skilled in the art that various modifications, improvements, combinations, etc. are possible.

### DESCRIPTION OF REFERENCE NUMERALS

11 First Node
12 Second Node
13 Third Node
14 Fourth Node
15 Pair of Nodes
21 First Branch Transmission Line
21I, 21J First Portion
21K First Connection Portion
22 Second Branch Transmission Line
22I, 22J Second Portion
22K Second Connection Portion
26 Divider
26A First-Stage Divider
26B Second-Stage Divider
26C Third-Stage Divider
26D Fourth-Stage Divider
30 Branch Source Transmission Line
31A, 31B Branch Transmission Line
32A, 32B Branched Transmission Line
33 Resistor
51 First Mixer
52 Second Mixer
53Rx First Receiving Terminal
53Tx First transmitting Terminal
54Rx Second Receiving Terminal
54Tx Second Transmitting Terminal
55 High-Frequency Circuit (Beamforming IC)
56 Antenna Element
56A First Feed Point
56B Second Feed Point
57 Feeder Line
60 Multilayer Board
60A First Surface
60B Second Surface
61 Ground Conductor

1. A high-frequency power dividing circuit, comprising:
a first node to which a high-frequency signal is input;
a plurality of second nodes from which high-frequency signals are output; and
a first branch transmission line connecting the first node to each of the plurality of second nodes, the first branch transmission line including a plurality of dividers being cascade-connected, each of the plurality of dividers having one input node and two output nodes, wherein at least one of the plurality of dividers being an unequal divider with a distribution ratio of 2 or less, the first branch transmission line configured to equally divide high-frequency power input to the first node to the plurality of second nodes.

2. The high-frequency power dividing circuit according to claim 1, wherein:
at least one of the plurality of dividers whose normalized power value of a high-frequency signal input to the input node is an even number has a distribution ratio of 1, the normalized power value being defined as a power value normalized by a power of a high-frequency signal output from each of the plurality of second nodes;
at least one of the plurality of dividers whose normalized power value of a high-frequency signal input to the input node is an odd number is configured to divide power so that a difference between the normalized power values of high-frequency signals after division is 1; and
the first branch transmission line terminates dividing power when the normalized power value of a high-frequency signal after division becomes 1.

3. The high-frequency power dividing circuit according to claim 2, wherein the at least one of the plurality of dividers whose normalized power value of the high-frequency signal input to the input node is an odd number 2m+1, where m is a natural number, has a distribution ratio of (m+1)/m.

4. The high-frequency power dividing circuit according to claim 1, wherein the number of the plurality of second nodes is 2×(2n+1), where parameter n is a natural number;
the plurality of dividers include a first-stage divider directly connected to the first node and two second-stage dividers each connected to a respective output of the first-stage divider;
the first-stage divider divides a power equally so that the normalized power value after division is 2n+1;
each of the second-stage dividers divides a power so that the normalized power values after division are n+1 and n.

5. The high-frequency power dividing circuit according to claim 1, further comprising:
a third node to which a high-frequency signal is input;
a plurality of fourth nodes from which high-frequency signals are output, the number of which is equal to the number of the plurality of second nodes;
a second branch transmission line connecting the third node to each of the plurality of fourth nodes and equally dividing a high-frequency signal input to the third node to the plurality of fourth nodes; and
a board on or within which the first branch transmission line and the second branch transmission line are formed;
wherein a plurality of node pairs are defined, each of the node pairs including one of the plurality of second nodes and one of the plurality of fourth nodes.

6. The high-frequency power dividing circuit according to claim 5, wherein
the number of the plurality of second nodes and the number of the plurality of fourth nodes are both even numbers,
the plurality of node pairs are arranged in two columns in a first direction parallel to a surface of the board to form two node pair columns,
the second node and the fourth node of each of the plurality of node pairs are arranged side by side in a second direction intersecting the first direction, and are arranged in a same positional relationship with respect to the second direction among the plurality of node pairs,
and wherein the first branch transmission line includes:
two first portions respectively arranged along the two node pair columns on a first side of each of the two node pair columns with respect to the second direction; and
a first connection portion connecting the two first portions at a location that does not overlap with the two node pair columns with respect to the first direction and connected to the first node;
and wherein the second branch transmission line includes:
two second portions respectively arranged along the two node pair columns on a second side of each of the two node pair columns opposite to the first side with respect to the second direction; and
a second connection portion connecting the two second portions at a location that does not overlap with the two node pair columns with respect to the first direction and connected to the third node.

7. The high-frequency power dividing circuit according to claim 1, wherein at least one of the dividers of the plurality of dividers is an equal divider.

8. The high-frequency power dividing circuit according to claim 1, wherein at least one of the plurality of dividers includes a pair of branch transmission lines and a resistor connected between the pair of branch transmission line.

9. The high-frequency power dividing circuit according to claim 1, wherein the number of the plurality of second nodes is an odd number.

10. An antenna module comprising:
the high-frequency power dividing circuit according to claim 1;
a first mixer configured to up-convert a baseband signal or an intermediate frequency signal to generate an up-converted signal, input the upconverted signal to the first node, and down-convert a high-frequency signal output from the first node;
a plurality of high-frequency circuits connected to the plurality of second nodes, respectively, and each of the plurality of high-frequency circuits having a function of amplifying a high-frequency signal output from a corresponding one of the plurality of second nodes to generate an amplified high-frequency signal;
a plurality of antenna elements connected to the high-frequency circuits, respectively, and fed with the amplified high-frequency signals;
wherein the plurality of high-frequency circuits are further configured to amplify high-frequency signals received by the plurality of antenna elements to generate received amplified high-frequency signals and input the received amplified high-frequency signals to the plurality of second nodes, respectively.

11. The antenna module according to claim 9, further comprising a multilayer board, wherein the plurality of high-frequency circuits are mounted on a first surface of the multilayer board and the plurality of antenna elements are arranged on a second surface of the multilayer board opposite the first surface.

12. An antenna module comprising:
a high-frequency power dividing circuit according to claim 4;
a first mixer configured to up-convert a baseband signal or an intermediate frequency signal to generate an up-converted signal, input the up-converted signal to the first node, and down-convert a high-frequency signal output from the first node;
a second mixer configured to up-convert a baseband signal or an intermediate frequency signal to generate an up-converted signal, input the up-converted signal to the third node, and down-convert a high-frequency signal output from the third node;
a plurality of high-frequency circuits, each of the high-frequency circuits being connected to the second node and the fourth node of each of the plurality of node pairs; and
a plurality of antenna elements connected to each of the plurality of high-frequency circuits,
wherein each of the plurality of high-frequency circuits separately amplifies a high-frequency signal input from the second node and a high-frequency signal input from the fourth node, and outputs amplified signals separately from output terminals, and supplies power of the amplified signals to the plurality of antenna elements,
and wherein each of the plurality of antenna elements includes a first feed point to which the amplified signal of a high-frequency signal input from the second node is input, and a second feed point to which the amplified signal of a high-frequency signal input from the fourth node is input, and radiates polarized waves, the polarized wave radiated when power is supplied to the first feed point being orthogonal to the polarized wave radiated when power is supplied to the second feed point.

13. The antenna module according to claim 12, wherein the numbers of the plurality of antenna elements connected to the respective high-frequency circuits are equal among the plurality of high-frequency circuits.

14. The antenna module according to claim 12, wherein:
the first mixer, the second mixer, and the plurality of high-frequency circuits are mounted on a first surface, which is one surface of the board;
the plurality of antenna elements are arranged on a second surface of the board opposite to the first surface;
each of the first branch transmission line and the second branch transmission line includes a conductor pattern arranged in an inner layer of the board; and
the board includes a plurality of ground conductors arranged in inner layers.

15. The antenna module according to claim 14, wherein the conductor pattern included in the first branch transmission line and the conductor pattern included in the second branch transmission line are two-fold rotationally symmetric with each other in a plan view and are arranged in a same single inner layer of the board.

16. The antenna module according to claim 12, further comprising:
a first terminal for transmitting and receiving connected to the first mixer and configured to connect to an external circuit; and
a second terminal for transmitting and receiving connected to the second mixer and configured to connect to an external circuit.

17. The antenna module according to claim 12, wherein a conductor pattern included in the first branch transmission line and a conductor pattern included in the second branch transmission line are arranged with two-fold rotational symmetry relative to each other in a plan view.

18. The antenna module according to claim 12, wherein the first branch transmission line and the second branch transmission line are arranged within mutually interdigitating U-shaped regions in a plan view.

19. The antenna module according to claim 12, wherein line lengths of two transmission lines extending from two output nodes of a first-stage divider to respective input nodes of two second-stage dividers in the first branch transmission line are equal.

20. The high-frequency power dividing circuit according to claim 1, wherein:
the plurality of dividers include at least one final-stage divider having two output nodes connected to the respective two of the plurality of second nodes;
the first branch transmission line includes two transmission lines with different line lengths connecting the two output nodes of the final-stage divider to the respective two of the plurality of second nodes;
the final-stage divider is an unequal divider with a distribution ratio of 2 or less, and the distribution ratio of the final-stage divider is set such that the difference in power between the high-frequency signals at the two of the plurality of second nodes connected to the final-stage divider is smaller than the difference in power between the high-frequency signals in a case where an equal divider is used as the final-stage divider.
